(19) United States
(12) Patent Application Publication
(10) Pub. No.: US 2005/0241585 A1
(43) Pub. Date: Nov. 3, 2005

(54) System for vaporizing materials onto a substrate surface

(75) Inventor: Ronald S. Cok, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/837,191

(22) Filed: Apr. 30, 2004

(51) Int. Cl. C23C 16/00

(52) U.S. Cl. 118/726; 427/248.1

(57) ABSTRACT

A system for vaporizing materials onto a substrate surface, comprising: a material deposition chamber containing a substrate; at least two separate source chambers, each source chamber having a material source containing a quantity of material and including controllable means for vaporizing the material in the source and creating a plume of vaporized material that is emitted into the deposition chamber and directly deposited on the substrate; independently controllable means for sealing each source chamber from the deposition chamber in a first mode, and for providing an opening for the plume of vaporized material to be directly deposited on the substrate in a second mode; independently controllable means for evacuating each source chamber; and independently controllable means for removing each source from its source chamber. The system provides a means to continuously deposit material on a substrate, and in particular thin films of organic materials, while reducing maintenance requirements and improving the control and purity of deposition.

### FIELD OF THE INVENTION

The present invention relates to the field of physical vapor deposition where a source material is heated to a temperature so as to cause vaporization and produce a vapor plume to form a thin film on a surface of a substrate.

### BACKGROUND OF THE INVENTION

An OLED device includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing and capability for full-color flat emission displays. Tang et al. described this multilayer OLED device in their U.S. Pat. Nos. 4,769,292 and 4,885,211.

Physical vapor deposition in a vacuum environment is the principal way of depositing thin organic material films as used in small molecule OLED devices. Such methods are well known, for example, Barr in U.S. Pat. No. 2,447,789 and Tanabe et al. in EP 0 982 411. The organic materials used in the manufacture of OLED devices are very sensitive to the deposition parameters, in particular to heat and contamination by humidity and oxygen. In consequence, they are deposited in a vacuum under carefully controlled conditions. For example, WO2003035925 A1 entitled “Device and Method for Vacuum Deposition, and Organic Electroluminescent Element Provided by the Device and the Method” by Kido, et al published 20030501 describes such a vacuum deposition device.

Equipment used in the manufacture of OLED devices is very expensive, including numerous vacuum chambers for the deposition of organic films, lithographic processing equipment, and equipment for the deposition of inorganic material. In consequence, the utilization of the equipment is a critical factor in a manufacturing process, in particular for the turn-around cycle time and maintenance down-time. As is well known, organic material deposition sources must be periodically recharged with organic material and the sources cleaned. Such recharging and cleaning tasks decrease the utilization of the manufacturing equipment. Even if replacement sources are available, the manufacturing process must be halted while the organic deposition machines are replaced.

Prior-art methods for improving equipment availability and manufacturing efficiency have employed larger containers or multiple sources. For example, WO2003035925 A1 referenced above describes a source with multiple circular openings for releasing evaporated materials. The Tokki Corporation markets Model Type ELVESS472CV(CM564) as a customizable evaporative material source that incorporates multiple cell-type evaporation sources in an array of turrets in a set. Each of the cell-type evaporation sources can be independently heated to reduce the overall time that material in the cell-type evaporation source is at an elevated temperature. While this approach decreases the frequency of down-time for a deposition system, it requires many additional sources, increased size and complexity, and does not address the fundamental problem.

DE10128091 C1 entitled “Vorrichtung für die Beschichtung eines flächigen Substrats” by Hoffman et al Granted 20021002 illustrates a deposition source having a long tube for transferring evaporated material. In an alternative prior-art method, an external gas feed is used to pipe gas into a deposition chamber. For example, DE10216671 A1 entitled “Beschichtungsanlage” by Geisler et al published 20031218 illustrates a dual-chamber device with gas feeds to each chamber. Such designs are problematic in the control of the vapor deposition, suffers from inadvertent deposition in the piping system that cannot be cleaned without stopping the manufacturing process, and is complex in structure.

There is a need, therefore, for an improved deposition apparatus for temperature-sensitive material that overcomes these objections.

### SUMMARY OF THE INVENTION

In accordance with one embodiment, the invention is directed towards a system for vaporizing materials onto a substrate surface, comprising:
a) a material deposition chamber containing a substrate;
b) at least two separate source chambers, each source chamber having a material source containing a quantity of material and including controllable means for vaporizing the material in the source and creating a plume of vaporized material that is emitted into the deposition chamber and directly deposited on the substrate;
c) independently controllable means for sealing each source chamber from the deposition chamber in a first mode, and for providing an opening for the plume of vaporized material to be directly deposited on the substrate in a second mode;
d) independently controllable means for evacuating each source chamber; and
e) independently controllable means for removing each source from its source chamber.

In a further embodiment, the invention is directed towards a method for the deposition of material on a substrate including the steps of:
a) providing a substrate in a material deposition chamber;
b) loading a first material source into an isolatable first source chamber;
c) loading a second material source into an isolatable second source chamber;
d) evacuating the deposition chamber and at least the first source chamber;
e) opening at least the first source chamber to the deposition chamber and evaporating material from the first material source onto the substrate;
f) sealing the first source chamber and removing the first material source;
g) evacuating the second source chamber;
h) opening the second source chamber to the deposition chamber and evaporating material from the second material source onto the substrate;
i) reloading the first source chamber with a loaded material source;
j) evacuating the reloaded first source chamber; and
k) opening the reloaded first source chamber to the deposition chamber and evaporating material from the loaded material source onto the substrate.

### Advantages

It is an advantage of the present invention that the system provides a means to continuously deposit material on a substrate, and in particular thin films of organic materials, while reducing maintenance requirements and improving the control and purity of deposition.

### BRIEF DESCRIPTION OF THE DRAWINGS

FIG. 1 is a cross-sectional view of one embodiment of a system according to the present invention for evaporating material and depositing the vapor onto a substrate; and

FIG. 2 shows an alternative view of the embodiment of FIG. 1 in a material deposition chamber; and

FIGS. 3a, 3b and 3c each depict portions of a flow diagram useful for describing a method of use for the present invention.

### DETAILED DESCRIPTION OF THE INVENTION

The problems of the prior art may be overcome through the use of a system for vaporizing materials, and in particular organic materials, to form a thin film on a substrate surface that comprises a material deposition chamber containing a substrate; at least two separate source chambers, each source chamber having a material source containing a quantity of material and including controllable means for vaporizing the material in the source and creating a plume of vaporized material that is emitted into the deposition chamber and directly deposited on the substrate; independently controllable means for sealing each source chamber from the deposition chamber in a first mode, and for providing an opening for the plume of vaporized material to be directly deposited on the substrate in a second mode; independently controllable means for evacuating each source chamber; and independently controllable means for removing each source from its source chamber.

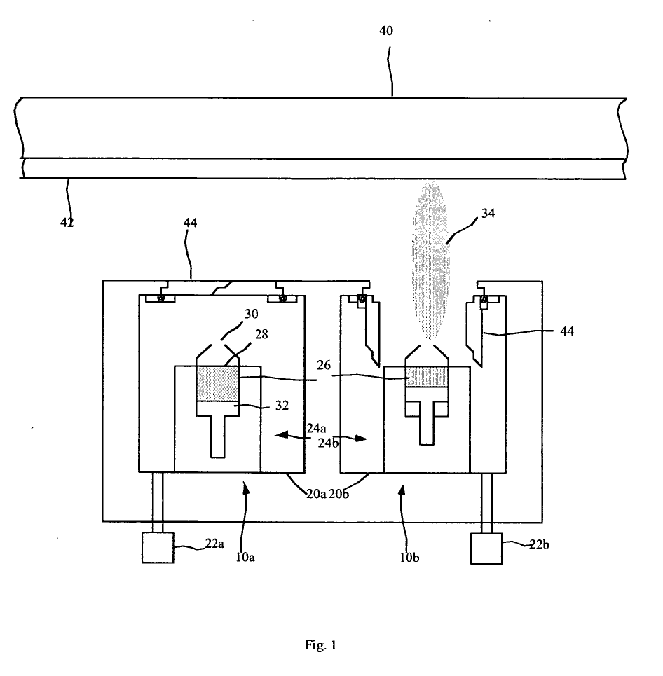

Referring to FIG. 1, two deposition apparatuses 10a and 10b are shown. The deposition apparatus 10a includes a source chamber 20a with independently controllable evacuation means 22a. The source chamber 20a may share a common wall (as shown) with a source chamber 20b of deposition apparatus 10b or be completely separated. An evaporative material source 24a is located within the source chamber 20a. Individual material sources which may be employed in the present system are known in the art, e.g. as described in the above referenced prior art. Additional apparatus which may be employed in the present system is described in commonly assigned U.S. patent application Ser. No. 10/352,558 (filed Jan. 28, 2003 by Jeremy M. Grace et al., entitled “Method of Designing a Thermal Physical Vapor Deposition System”), Ser. No. 10/784,585 (filed Feb. 23, 2004 by Michael Long et al., entitled “Device and Method for Vaporizing Temperature Sensitive Materials”), ______ and (Kodak Docket 87898, filed concurrently herewith, by Ronald Cok et al.), the disclosures of which are herein incorporated by reference. The material source may be implemented in a variety of ways as is known in the prior art, for example, point or linear sources may be employed. In one embodiment, as shown in FIG. 1, the material source 24a includes material 26, a heating element 28 (e.g., electrically resistive wires, induction, radiant or RF coupling heating means) for evaporating the material 26, an aperture 30 for releasing the vaporized material 34 and mechanical feeding means 32 (e.g., piston) for feeding the material into the heating element.

The material source thus creates a plume of vaporized material 34 for deposition onto a nearby substrate 40, optionally through a mask 42, to form a thin film on the substrate 40. The source heating element 28 may be turned on and off to control the formation of the plume of evaporated material. The deposition apparatus 10b includes the complementary elements described for deposition apparatus 10a.

Each source chamber includes sealing means 44 for providing a vacuum seal between the source chamber and the deposition chamber when closed, and an opening for allowing the plume of evaporated material to escape and directly deposit on the substrate 40 when open. As used herein, directly deposit means that the evaporated materials, once emitted from the material source 24a or 24b may travel directly onto the substrate 40 without striking a chamber wall or other obstacle. Such direct deposit provides improved deposition control and purity and reduces the need for cleaning.

A variety of means may be employed to seal the chamber as is known to those skilled in the mechanical arts. As shown in FIG. 1, a pair of rotating doors can swing open to expose the plume of evaporated materials or may be closed to provide a vacuum-tight seal. Additional sealing elements may be employed as may single door designs or other rotating or translational mechanisms. The evaporative material sources 24a and 24b may be removed from the source chambers 20a and 20b when the sealing means 44 is closed.

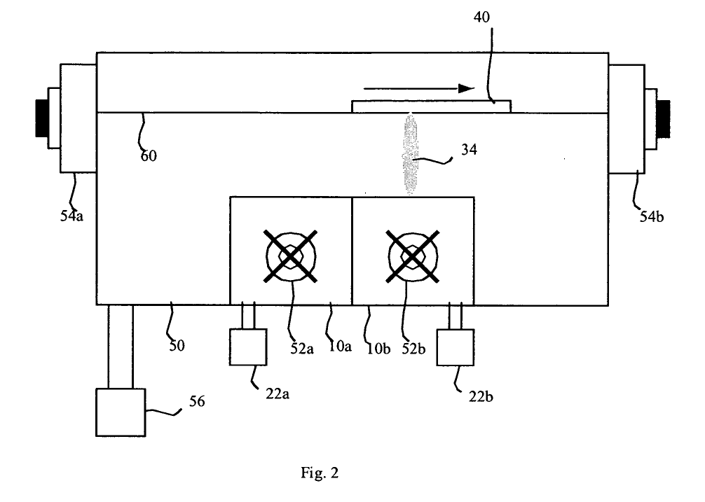

Referring to FIG. 2, the source chambers 20a and 20b are integrated into the thin-film material deposition chamber 50. Independently controllable access means 52a and 52b (for example a mechanical interlock with a seal) provide access into the individual source chambers 20a and 20b respectively to remove the material sources 24a and 24b when opened and, when closed, seal the source chamber against the external atmosphere. Evacuation means 22a and 22b may include, e.g., independently controllable vacuum pumps as are known in the art to independently control the evacuation of the source chambers 20a and 20b. Evacuation means 56 provides means to evacuate the deposition chamber 50, e.g. using commercially available vacuum pumps. Hence, the independently controllable evacuation means 22a, 22b, and 56 can independently evacuate the source chambers 20a, 20b, and deposition chamber 50 as desired. Moreover, by opening the sealing means 44, either or both source chambers 20a and 20b can be opened to the deposition chamber 50. By closing the sealing means 44 for either of the source chambers 20a, 20b and opening the corresponding access port 52a or 52b, the corresponding material source 24a, 24b can be isolated from the deposition chamber 50 and removed from its corresponding source chamber 20a or 20b without affecting the vacuum in the deposition chamber 50 or the other source chamber. Hence, one source chamber can be opened and the material source removed while the other source chamber and the deposition chamber 50 are evacuated and the other material source operative.

The substrate 40 can be introduced into the deposition chamber 50 through deposition chamber access ports 54a and 54b. The substrate may be transported on a support 60 (as shown) or the substrate may itself be a continuous substrate. The deposition chamber may include further mechanical devices for mask alignment or selection or substrate movement (not shown). In particular, the substrate movement may be continuous or a plurality of substrates may be continuously moved past the material sources and have thin films of material deposited upon them. Such mechanical and/or robotic means for transporting substrates in a vacuum are well-known in the art.

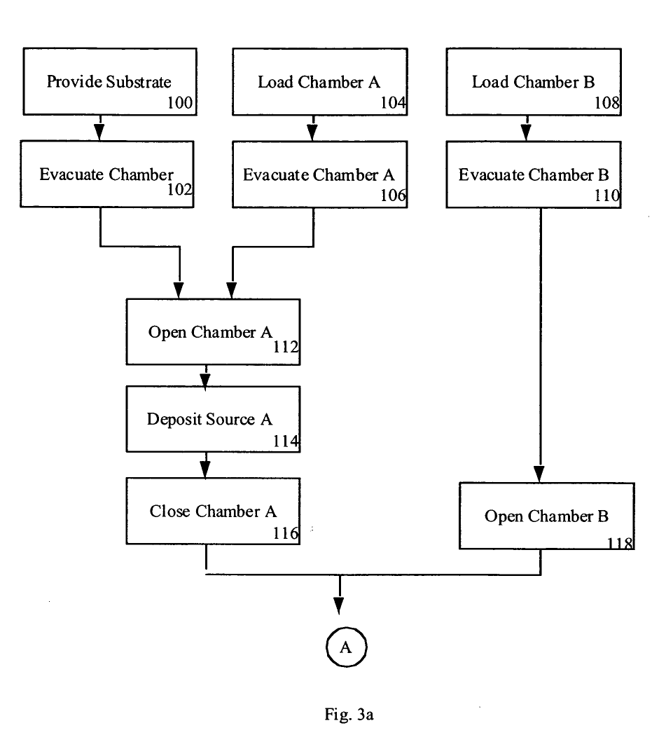

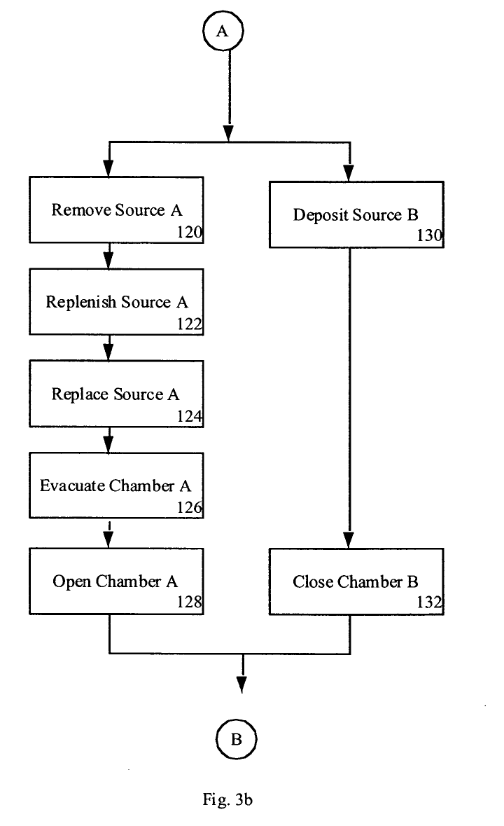

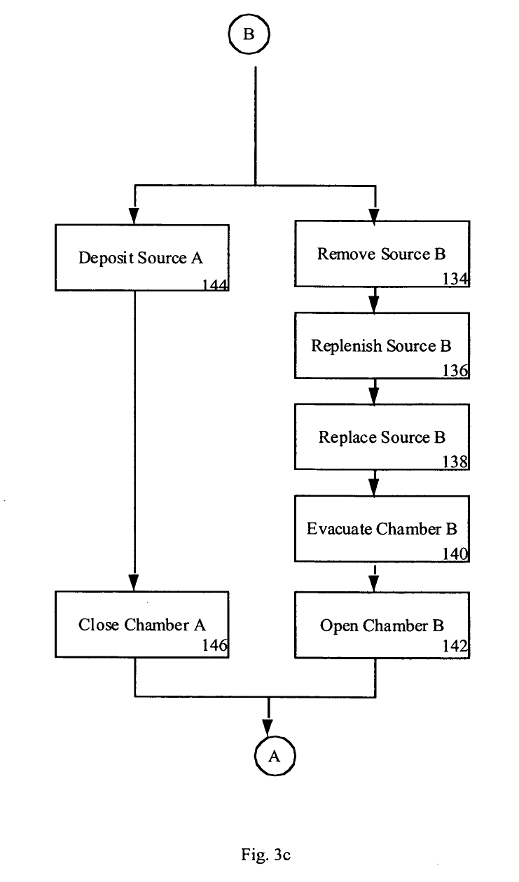

Referring to FIG. 3a, in operation the system for vaporizing materials is first initialized by providing 100 substrates within the deposition chamber and then evacuating 102 the deposition chamber. At the same time a first material source A (initially charged with material) is loaded 104 into source chamber A and then source chamber A is evacuated 106. A second material source B (likewise initially charged with material) is likewise loaded 108 into source chamber B and then source chamber B is evacuated 110.

Once the deposition and source chamber A are loaded and evacuated, sealing means 44 of source chamber A may be opened 112 and deposition 114 can begin from source A. Deposition from material source A continues until the material is used up, at which time the sealing means for source chamber A is closed 116. Either before or after source chamber A is closed 116, the sealing means for source chamber B, being evacuated, may be opened 118. The closing of one chamber and the opening of the other may be scheduled for a time between moving substrates so that no interruption in deposition on substrates may be experienced. Alternatively, the two sources A and B may simultaneously deposit material at a controlled and complementary rate on a common substrate. This is particularly useful if a continuous deposition on a continuous substrate is desired.

Referring to FIG. 3b, after the material source A is exhausted and its sealing means closed, the material source A may be removed 120 by opening the access lock 52a and physically removing the material source A from the source chamber A. The material source A may then be replenished 122 and replaced 124 into the source chamber, the access lock 52a closed, and the source chamber evacuated 126. Replenishing of a source may optionally include cleaning of the material source as well as reloading of material. The source chamber may also be cleaned while it is isolated from the deposition chamber. Once the source chamber A is evacuated 126, it the sealing means may be opened 128.

At the same time as the material source A is being replenished, deposition 130 from source B continues. When the supply of material from source B is exhausted, the source chamber B sealing means is closed 132. As in the prior steps, the sealing means for source chamber B may be closed 132 at the same time as, before, or after, the sealing means for source A is opened 128.

Referring to FIG. 3c, once material source B is exhausted and the sealing means closed, it is removed 134 by reopening the lock 52b and removing the material source B. The material source B is then replenished 136 and replaced 138. The source chamber B is then evacuated 140 and the sealing means opened 142. At the same time as the material source B is being replenished, deposition 144 from source A continues. When the supply of material from material source A is exhausted, the source chamber sealing means is closed 146. As in the prior steps, the sealing means for material source A may be closed 146 at the same time as, before, or after, the sealing means for source B is opened 142.

At this point the entire cycle of depositing and exhausting material from source A while source B is replenished is repeated. This cycle may be repeated as often as desired without the need to halt deposition onto a substrate. A continuous supply of separate substrates may have thin films deposited on them in this way or, alternatively, a continuous substrate may have deposited upon it a continuous thin film. Because the material sources are alternately and periodically removed from the deposition chamber, a continuous deposition process may be employed for coating thin films of evaporated material onto substrates. Because the evaporated material is directly applied to the substrates rather than through an external supply system, a simpler and more easily controlled deposition process with fewer contaminants is provided.

While FIGS. 3a, 3b, 3c describe an embodiment wherein two material sources are alternatively exhausted and replenished, additional embodiments are envisioned. For example, more than two material sources may be employed in rotation in the two source chambers. Such embodiment may be preferred where the replenishing and cleaning of a material source takes a longer period of time than exhaustion of a single source. Alternatively, disposable material sources may be used rather than replenishing previously used sources. In yet another alternative, more than two source chambers may be employed in rotation. This embodiment would be particularly useful where the cleaning of a source chamber takes a longer period of time than exhaustion of a single source.

The invention has been described in detail with particular reference to certain preferred embodiments thereof, but it will be understood that variations and modifications can be effected within the spirit and scope of the invention.

### PARTS LIST

10a, 10b deposition apparatus
20a, 20b source chamber
22a, 22b evacuation means
24a, 24b material source
26 material
28 heating element
30 aperture
32 feeding means
34 vaporized material
40 substrate
42 mask
44 sealing means
50 deposition chamber
52a, 52b access means
54a, 54b access port
56 evacuation means
60 support
100 providing step
102 evacuating step
104 loading step
106 evacuating step
108 loading step
110 evacuating step
112 open step
114 deposition step
116 close step
118 open step
120 remove step
122 replenish step
124 replace step
126 evacuate step
128 open step
130 deposit step
132 close chamber
134 remove step
136 replenish step
138 replace step
140 evacuate step
142 open step
144 deposition step
146 close step

1. A system for vaporizing materials onto a substrate surface, comprising:
a) a material deposition chamber containing a substrate;
b) at least two separate source chambers, each source chamber having a material source containing a quantity of material and including controllable means for vaporizing the material in the source and creating a plume of vaporized material that is emitted into the deposition chamber and directly deposited on the substrate;
c) independently controllable means for sealing each source chamber from the deposition chamber in a first mode, and for providing an opening for the plume of vaporized material to be directly deposited on the substrate in a second mode;
d) independently controllable means for evacuating each source chamber; and
e) independently controllable means for removing each source from its source chamber.

2. The system claimed in claim 1 wherein the material source is a linear source.

3. The system claimed in claim 1 wherein the material source is a point source.

4. The system claimed in claim 1 wherein the material source is a planar source.

5. The system claimed in claim 1 wherein the substrate is a continuous substrate.

6. The system claimed in claim 1 further comprising a plurality of discrete substrates mounted on a movable support.

7. A method for the deposition of material on a substrate including the steps of:
a) supplying a substrate within a material deposition chamber;
b) providing at least two separate source chambers, each source chamber having a material source containing a quantity of material;
c) alternatively vaporizing the material in each source and creating a plume of vaporized material that is emitted into the deposition chamber and directly deposited on the substrate;
d) alternatively sealing each source chamber from the deposition chamber in a first mode, and providing an opening for the plume of vaporized material to be directly deposited on the substrate in a second mode;
e) alternatively evacuating each source chamber; and
f) alternatively removing each source from its source chamber.

8. A method for the deposition of material on a substrate including the steps of:
a) providing a substrate in a material deposition chamber;
b) loading a first material source into an isolatable first source chamber;
c) loading a second material source into an isolatable second source chamber;
d) evacuating the deposition chamber and at least the first source chamber;
e) opening at least the first source chamber to the deposition chamber and evaporating material from the first material source onto the substrate;
f) sealing the first source chamber and removing the first material source;
g) evacuating the second source chamber;
h) opening the second source chamber to the deposition chamber and evaporating material from the second material source onto the substrate;
i) reloading the first source chamber with a loaded material source;
j) evacuating the reloaded first source chamber; and
k) opening the reloaded first source chamber to the deposition chamber and evaporating material from the loaded material source onto the substrate.

9. The method claimed in claim 8, wherein the first material source is replenished and the first source chamber is reloaded in step i) with the replenished first material source.

10. The method claimed in claim 9, further comprising cleaning the first material source prior to reloading in step i).

11. The method claimed in claim 8, further comprising cleaning the first source chamber prior to reloading in step i).

12. The method claimed in claim 8, wherein first source chamber is reloaded in step i) with a third material source.

13. The method claimed in claim 8, further comprising:
l) sealing the second source chamber and removing the second material source;
m) reloading the second source chamber with a loaded material source;
n) evacuating the reloaded second source chamber; and
o) opening the reloaded second source chamber to the deposition chamber and evaporating material from the loaded material source in the second source chamber onto the substrate.

14. The method claimed in claim 13, wherein the first and second material sources are replenished, and the first source chamber is reloaded in step i) and the second source chamber is reloaded in step m) with replenished material sources.

15. The method claimed in claim 13, wherein first source chamber is reloaded in step i) with a third material source.

16. The method claimed in claim 8, wherein the substrate moves continuously.

17. The method claimed in claim 16, wherein a plurality of discrete substrates are provided in the deposition chamber.

18. The method claimed in claim 8, wherein the substrate is a continuous substrate.
